(19) United States
(12) Patent Application Publication
(10) Pub. No.: US 2024/0371785 A1
(43) Pub. Date: Nov. 7, 2024

(54) PACKAGE STRUCTURE AND MANUFACTURING METHOD THEREOF

(71) Applicant: Powertech Technology Inc., Hsinchu County (TW)

(72) Inventors: Ching-Wei Liao, Hsinchu County (TW); Shang-Yu Chang Chien, Hsinchu County (TW)

(73) Assignee: Powertech Technology Inc., Hsinchu County (TW)

(21) Appl. No.: 18/608,969

(22) Filed: Mar. 19, 2024

(30) Foreign Application Priority Data
May 5, 2023 (TW) 112116866

(51) Int. Cl. H01L 23/544; H01L 23/00; H01L 23/31; H01L 23/498; H01L 25/00; H01L 25/10

(52) U.S. Cl. CPC H01L 23/544; H01L 23/3128; H01L 23/49833; H01L 23/49838; H01L 24/16; H01L 24/32; H01L 24/73; H01L 24/94; H01L 25/105; H01L 25/50; H01L 2223/54413; H01L 2223/54426; H01L 2224/16225; H01L 2224/32225; H01L 2224/73204; H01L 2224/94; H01L 2225/1058; H01L 2924/161; H01L 2924/181

(57) ABSTRACT

A package structure including a chip, an encapsulant, a first redistribution circuit structure, a second redistribution circuit structure, a conductive member, and a coded structure is provided. The encapsulant has a first encapsulating surface and a second encapsulating surface opposite thereto. The encapsulant covers the chip. The first redistribution circuit structure is disposed on the first encapsulating surface of the encapsulant. The second redistribution circuit structure is disposed on the second encapsulating surface of the encapsulant. The chip is electrically connected to the first redistribution circuit structure or the second redistribution circuit structure. The conductive member penetrates through the encapsulant to be electrically connected to the first redistribution circuit structure and the second redistribution circuit structure. The coded structure is disposed on the second redistribution circuit structure. The coded structure includes a readable coded pattern.

### CROSS-REFERENCE TO RELATED APPLICATION

This application claims the priority benefit of Taiwan application serial no. 112116866, filed on May 5, 2023. The entirety of the above-mentioned patent application is hereby incorporated by reference herein and made a part of this specification.

### BACKGROUND OF THE INVENTION

### Field of the Invention

The invention relates to a package structure and a manufacturing method thereof, and in particular to a chip package structure having a coded structure and a manufacturing method thereof.

### Description of Related Art

With the advancement of science and technology, electronic products also tend to diversify according to market demand. For package structures containing chips, the appearances thereof may be the same or similar, but the chips, circuits, or other elements that are more difficult to be directly identified in appearance therein may be adjusted differently according to design requirements. Therefore, how to efficiently track, identify, or recognize the manufacturing process or the finished product of the package structure, and/or to effectively manage the manufacturing process or the finished product of the package structure has become a research topic at present.

### SUMMARY OF THE INVENTION

The invention provides a package structure and a manufacturing method thereof having a coded structure.

A package structure of the invention includes a first chip, an encapsulant, a first redistribution circuit structure, a second redistribution circuit structure, a conductive member, and a coded structure. The encapsulant has a first encapsulating surface and a second encapsulating surface opposite to the first encapsulating surface. The encapsulant covers the first chip. The first redistribution circuit structure is disposed on the first encapsulating surface of the encapsulant. The second redistribution circuit structure is disposed on the second encapsulating surface of the encapsulant. The first chip is electrically connected to the first redistribution circuit structure or the second redistribution circuit structure. The conductive member penetrates through the encapsulant to be electrically connected to the first redistribution circuit structure and the second redistribution circuit structure. The coded structure is disposed on the second redistribution circuit structure. The coded structure includes a readable coded pattern.

A manufacturing method of a package structure of the invention includes the following steps: forming a first redistribution circuit structure; forming a conductive member on the first redistribution circuit structure; disposing a first chip on the first redistribution circuit structure; forming an encapsulant on the first redistribution circuit structure to cover the first chip; forming a second redistribution circuit structure on the encapsulant, wherein the first chip is electrically connected to the first redistribution circuit structure or the second redistribution circuit structure, and the conductive member penetrates through the encapsulant to be electrically connected to the first redistribution circuit structure and the second redistribution circuit structure; and forming a coded structure on the encapsulant, wherein the coded structure includes a readable coded pattern.

Based on the above, via the coded structure, efficient product tracking, identification, or recognition may be performed during the manufacturing process of the package structure or on the finished product thereof, and/or the manufacturing process of the package structure or the finished product thereof may be efficiently managed.

### BRIEF DESCRIPTION OF THE DRAWINGS

FIG. 1A to FIG. 1G are partial cross-sectional schematic diagrams of a partial manufacturing method of a package structure according to the first embodiment of the invention.

FIG. 1H is a partial cross-sectional schematic diagram of a package structure according to the first embodiment of the invention.

FIG. 1I is a partial cross-sectional schematic diagram of a package structure according to the first embodiment of the invention.

FIG. 1J is a partial cross-sectional schematic diagram of a package structure according to the first embodiment of the invention.

FIG. 1K to FIG. 1L are partial top view schematic diagrams of a partial manufacturing method of a package structure according to the first embodiment of the invention.

FIG. 1M is a partial top view schematic diagram of a package structure according to the first embodiment of the invention.

FIG. 1N is a partial cross-sectional schematic diagram of a package structure according to the first embodiment of the invention.

FIG. 2A to FIG. 2E are partial cross-sectional schematic diagrams of a partial manufacturing method of a package structure according to the second embodiment of the invention.

FIG. 2F is a partial cross-sectional schematic diagram of a package structure according to the second embodiment of the invention.

FIG. 2G is a partial cross-sectional schematic diagram of a package structure according to the second embodiment of the invention.

FIG. 3A to FIG. 3C are partial cross-sectional schematic diagrams of a partial manufacturing method of a package structure according to the third embodiment of the invention.

FIG. 3D is a partial cross-sectional schematic diagram of a package structure according to the third embodiment of the invention.

FIG. 3E is a partial cross-sectional schematic diagram of a package structure according to the third embodiment of the invention.

### DESCRIPTION OF THE EMBODIMENTS

Unless expressly stated otherwise, directional terms (e.g., up, down, top, bottom) used herein are used by way of referencing drawn figures only and are not intended to imply absolute orientation.

Any method described herein is in no way intended to be construed as requiring performance of the steps thereof in a particular order, unless expressly stated otherwise.

The singular “a”, “an”, or “the” and similar terms include plural references unless expressly stated otherwise.

Similar terms such as “first”, “second”, and “third” may be used to describe various elements, but these elements should not be limited by these terms. These terms are used only to distinguish one element from another, and do not define an order of execution or a structural orientation relationship.

The numerical value or the derivative relationship of the numerical value expressed in the specification (such as: the comparison or trend of a ratio) may include the stated numerical value and the deviation value within the range of deviation acceptable to those having ordinary skill in the art. The above deviation value may be one or a plurality of standard deviations in the manufacturing process or measurement process or the calculation error caused by other factors such as the number of digits used, rounding, or error propagation in the calculation or conversion process.

The invention is more comprehensively described with reference to the figures of the present embodiments. However, the invention may also be implemented in various different forms, and is not limited to the embodiments in the present specification. The thickness, size, or magnitude of layers or regions in the drawings may be exaggerated for clarity. The same or similar reference numerals represent the same or similar elements and are not repeated in the following paragraphs.

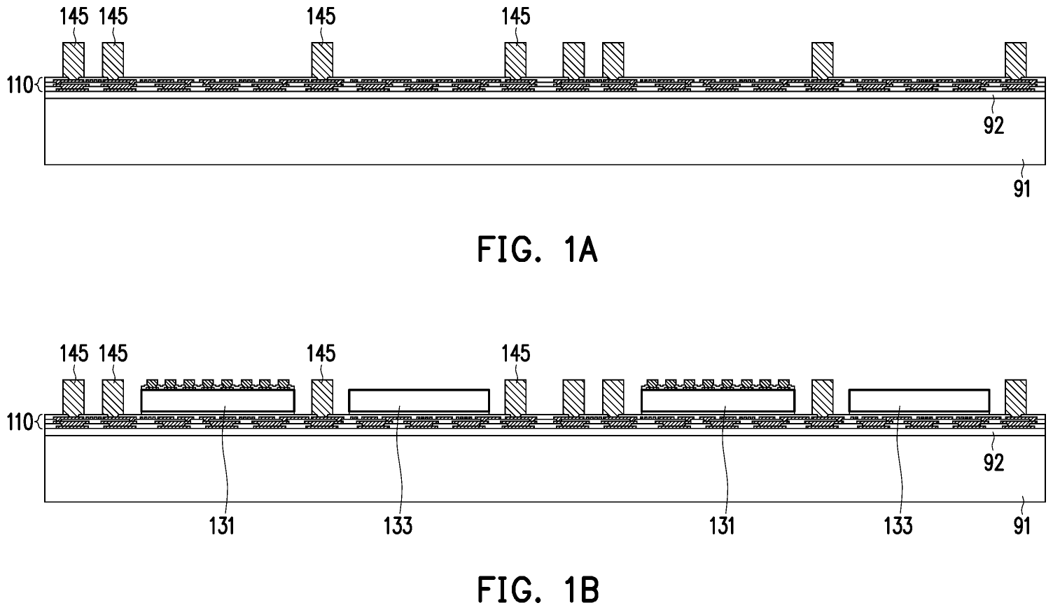

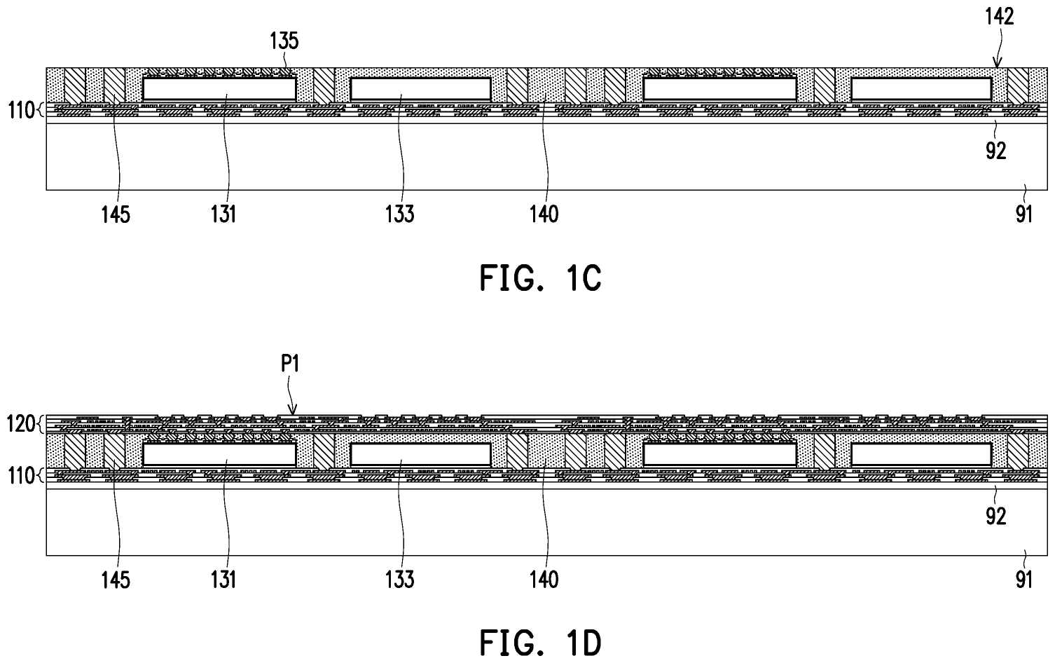

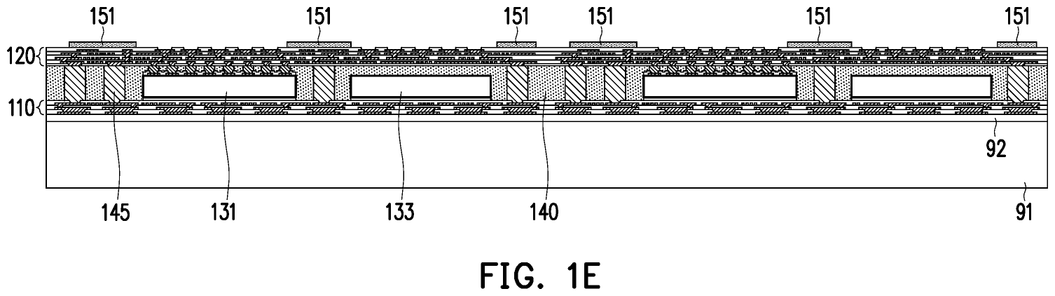

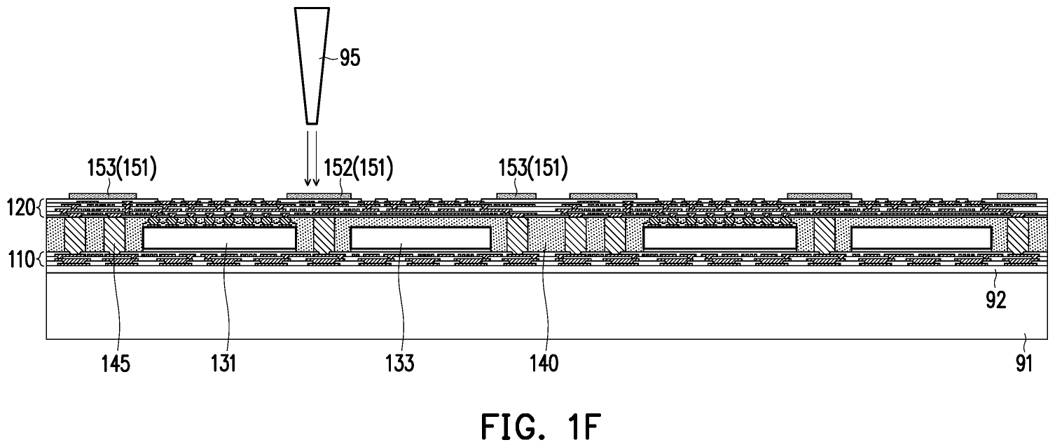

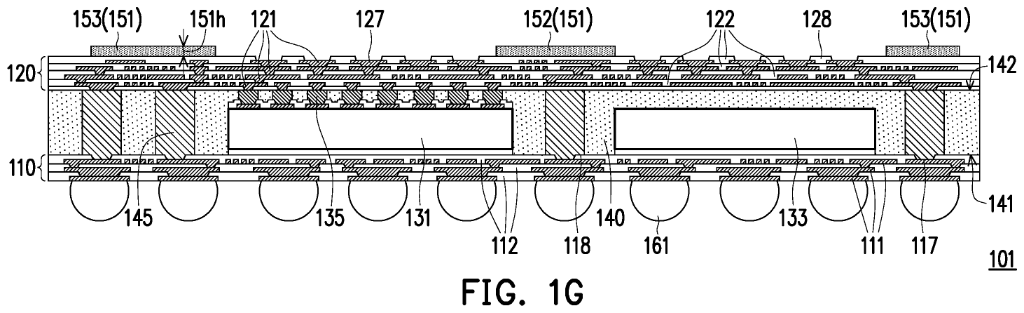

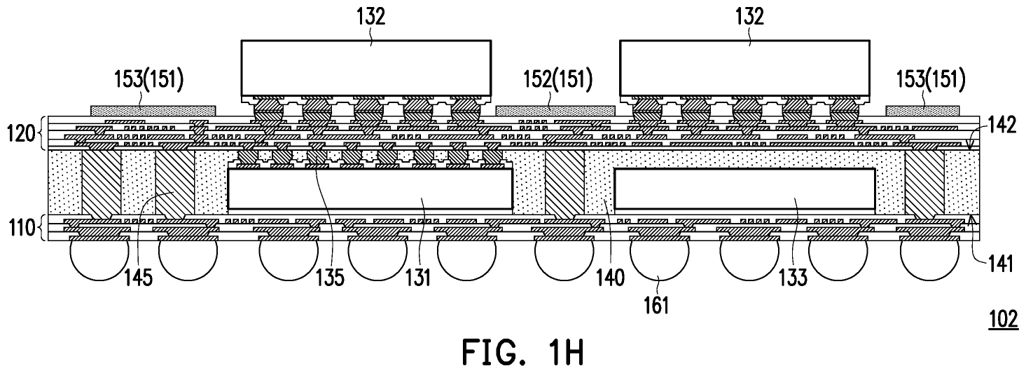

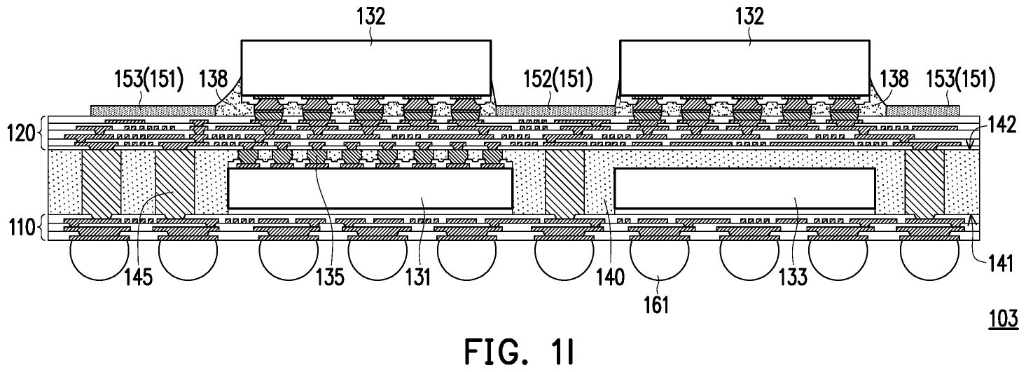

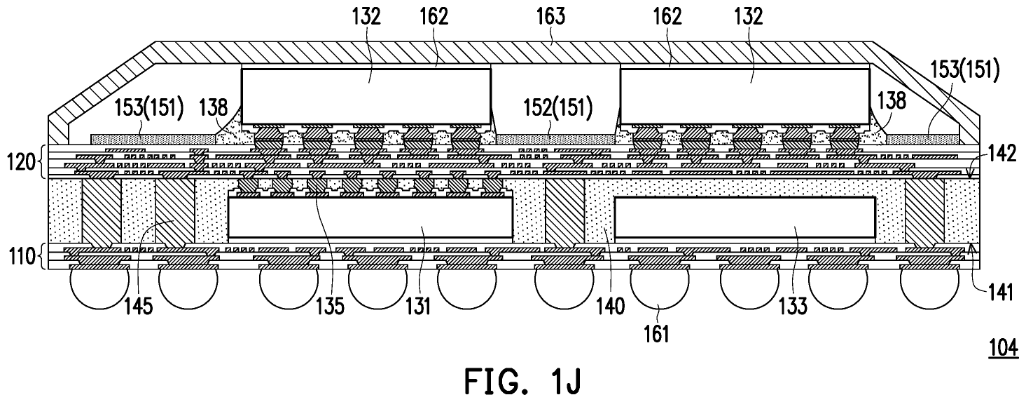

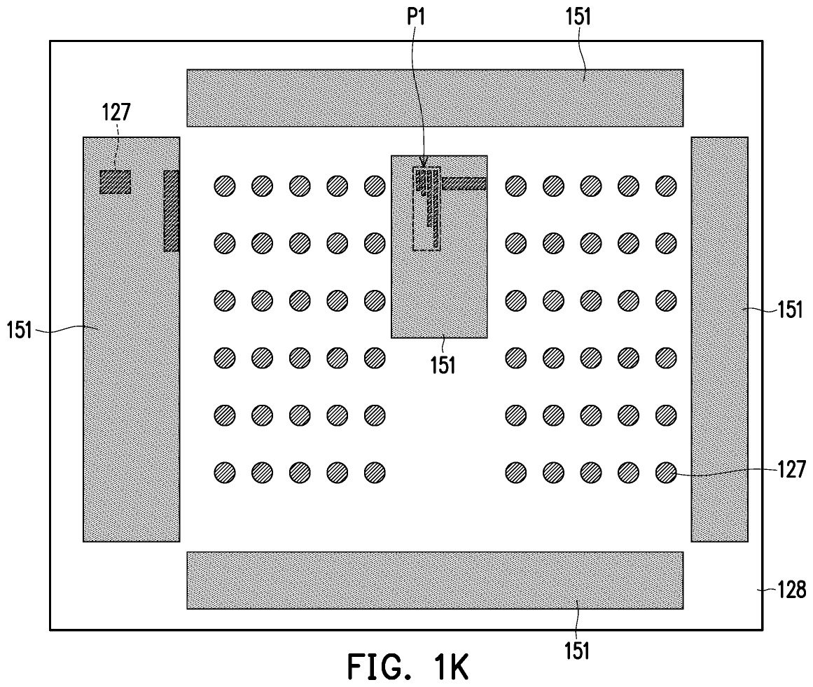

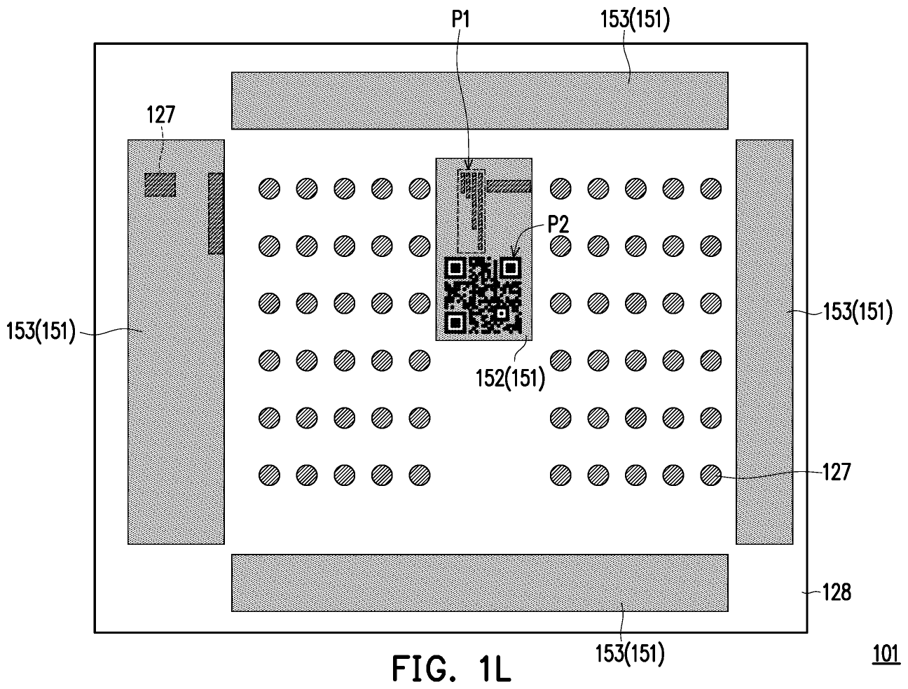

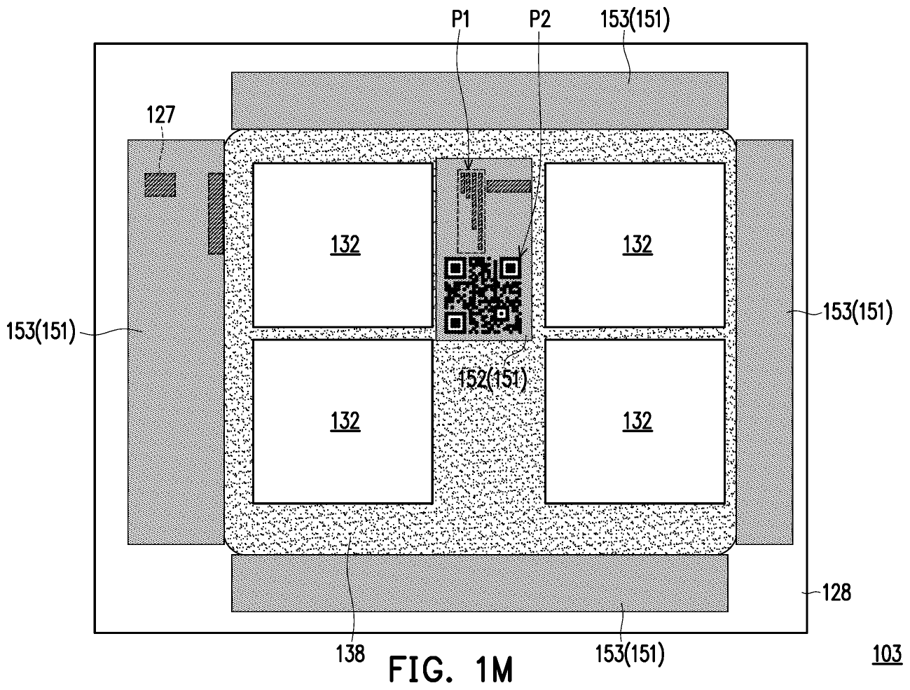

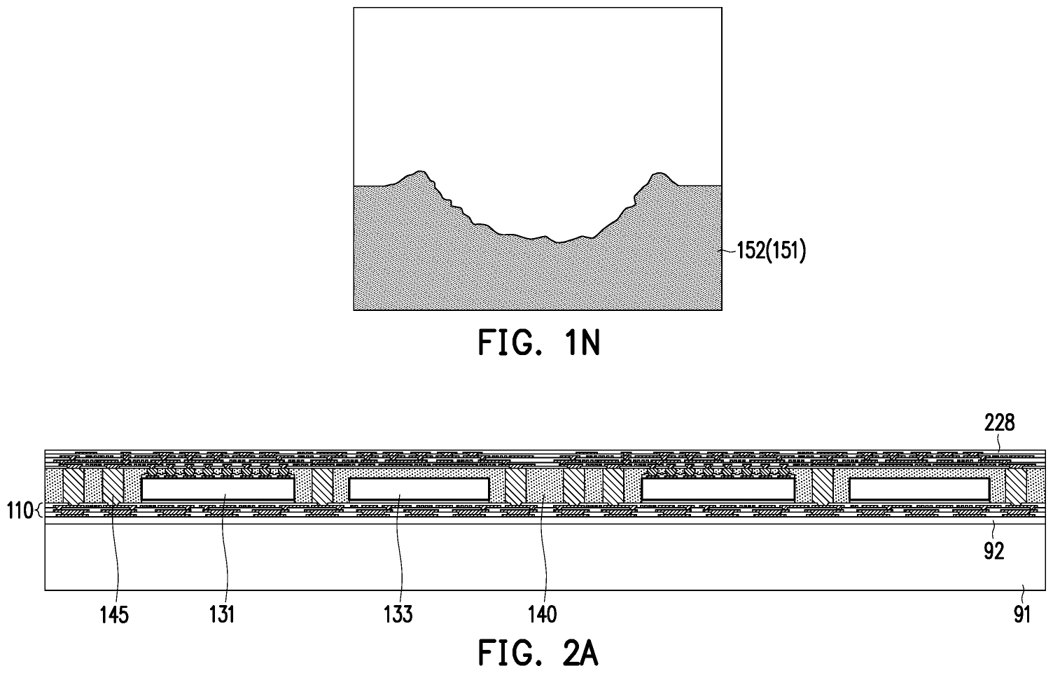

FIG. 1A to FIG. 1G are partial cross-sectional schematic diagrams of a partial manufacturing method of a package structure according to the first embodiment of the invention. FIG. 1K to FIG. 1L are partial top view schematic diagrams of a partial manufacturing method of a package structure according to the first embodiment of the invention. For example, FIG. 1K may be a top view schematic diagram corresponding to a portion of FIG. 1E, and/or FIG. 1L may be a top view schematic diagram corresponding to a portion of FIG. 1G.

Referring to FIG. 1A, a first redistribution circuit structure 110 is formed on a carrier 91. The invention has no special limitation on the carrier 91, as long as the carrier 91 is adapted to support the film layer formed thereon or the elements disposed thereon.

In the present embodiment, the carrier 91 may have a release layer 92, but the invention is not limited thereto. The release layer 92 is, for example, a light to heat conversion (LTHC) adhesive layer or other similar release layers 92, and the invention is not limited thereto.

The first redistribution circuit structure 110 may include a corresponding conductive layer 111 (indicated in FIG. 1G) and a corresponding insulating layer 112 (indicated in FIG. 1G). The first redistribution circuit structure 110 may be formed by a commonly used semiconductor process (e.g., coating process, deposition process, photolithography process, and/or etching process), so details are not repeated here. The number of layers of the conductive layer 111 and/or the insulating layer 112 is not limited in the invention. In addition, in FIG. 1A or other similar figures, the form of the conductive layer 111 and/or the insulating layer 112 is only shown as an example. For example, even though two adjacent conductive layers 111 are not connected in the cross section shown in FIG. 1A, they may still be connected in other cross-sections not shown. A corresponding portion of the conductive layer 111 may form a corresponding circuit. In addition, the layout design of the above circuit may be adjusted according to design requirements, which is not limited in the invention.

In addition, in order to make the drawings concise and clear, the conductive layer 111 and/or the insulating layer 112 are not directly marked in FIG. 1A or other similar drawings. A portion of the conductive layer 111 and/or the insulating layer 112 in the first redistribution circuit structure 110 may be as provided in FIG. 1G. In FIG. 1A or other similar figures, the corresponding boxed regions including oblique lines in the first redistribution circuit structure 110 may be the corresponding conductive layer 111, and/or the corresponding blank boxed region in the redistribution circuit structure may be the corresponding insulating layer 112.

In an embodiment, a top insulating layer 118 (i.e., the insulating layer 112 farthest from the carrier 91) may have an opening, and the opening may expose a portion of a top conductive layer 117 (i.e., the conductive layer 111 farthest from the carrier 91).

In an embodiment, the material of the insulating layer 112 of the first redistribution circuit structure 110 is, for example, polyimide (PI), other suitable organic insulating materials, or a stack or combination thereof.

Please continue to refer to FIG. 1A, a plurality of conductive members 145 are formed on the first redistribution circuit structure 110.

In an embodiment, the conductive members 145 may be embedded in the opening of the topmost insulating layer 112 to be connected to the topmost conductive layer 111.

In an embodiment, the conductive members 145 may be formed by a commonly used semiconductor process (such as photolithography process, sputtering process, electroplating process, and/or etching process), but the invention is not limited thereto. For example, the conductive members 145 may include a plating core layer and a seed layer surrounding the plating core layer. For example, the conductive members 145 may include a seed layer and a plating core layer disposed on the seed layer. In an embodiment, the seed layer and/or the plating core layer may include a copper layer. For example, the seed layer may include a copper layer formed by a sputtering process, and the plating core layer may include a copper layer formed by an electroplating process. In addition, for clarity, not all the conductive members 145 are marked one by one in FIG. 1A or other similar figures.

Referring to FIG. 1B, a plurality of first chips 131 are disposed on the first redistribution circuit structure 110.

In an embodiment, the first chips 131 may be disposed on the first redistribution circuit structure 110 in such a manner that the backside thereof faces the first redistribution circuit structure 110. In an embodiment, there may be a suitable adhesive material (e.g., die attach film (DAF)) between the backside of the first chips 131 and the first redistribution circuit structure 110, but the invention is not limited thereto.

In an embodiment not shown, chips similar to the first chips 131 may be disposed on the first redistribution circuit structure 110 and electrically connected thereto by means of flip-chip bonding.

Please continue to refer to FIG. 1B, in an embodiment, a plurality of rigid elements 133 may be disposed on the first redistribution circuit structure 110.

In an embodiment, there may be a suitable adhesive material (such as DAF) between the rigid elements 133 and the first redistribution circuit structure 110, but the invention is not limited thereto.

In an embodiment, the rigid elements 133 may include electronic elements. For example, the rigid elements 133 may include resistors, capacitors, or other suitable passive elements. For another example, the rigid elements 133 may include chips.

In an embodiment, the rigid elements 133 may include a dummy device on electrical signals, and, for example, in a subsequent application, there may not be any conductive elements for transmitting electrical signals connected to the dummy device. However, the dummy device on electrical signals does not exclude the possibility of being used as electromagnetic interference (EMI) shielding, grounding element (e.g.: floating ground), or other adaptive applications.

In an embodiment, the rigid elements 133 may be used as support during the manufacturing process and/or on the subsequent structure, adjustment of thermal expansion, adjustment of flatness, or other possibilities for adaptive applications.

It should be noted that the invention does not limit the configuration sequence of the first chips 131 and the rigid elements 133.

It should be noted that, in FIG. 1A and FIG. 1B, the conductive members 145 are formed first; then, the first chips 131 are disposed, but the invention is not limited thereto. In an embodiment not shown, the first chips 131 may be disposed first; then, the conductive members 145 are formed.

Referring to FIG. 1C, an encapsulant 140 covering the first chips 131 is formed. The encapsulant 140 may expose the top surface of the conductive members 145.

For example, a molding compound (e.g., epoxy resin; not shown) covering the first chips 131 may be formed on the first redistribution circuit structure 110. Then, the molding compound is cured by a suitable means (such as heating, lighting, and/or left to stand); after that, the encapsulant 140 may be correspondingly formed. That is, the encapsulant 140 may be formed by a molding compound.

In the present embodiment, the conductive members 145 may be formed on the first redistribution circuit structure 110 first; then, the encapsulant 140 at least laterally covering the conductive members 145 is formed on the first redistribution circuit structure 110.

In an embodiment, after the molding compound is cured, a portion of the cured molding compound may be removed by grinding, planarizing, or other suitable processes.

In an embodiment, the active surface of the first chips 131 may have a chip connecting member 135. The encapsulant 140 may expose the top surface of the chip connecting member 135. In addition, for clarity, not all the chip connecting members 135 are marked one by one in FIG. 1C or other similar figures.

In an embodiment, the surface of the encapsulant 140 (which may be referred to as the second encapsulating surface), the top surface of the chip connecting members, and the top surface of the conductive members 145 may be flat surfaces.

In an embodiment not shown, a photo imageable dielectric (PID) material may be formed on the first redistribution circuit structure 110 first; then, a dielectric opening exposing the topmost conductive layer 111 is formed on the PID material at least via a photolithography process; then, a conductive member (the structure of which may be similar to the conductive members 145) connected to the topmost conductive layer 111 is formed in the dielectric opening via a commonly used semiconductor process. That is, the encapsulant 140 may be formed by a PID material.

In a possible embodiment, the encapsulant that is the same as or similar to the encapsulant 140 may be a homogeneous material, and the homogeneous material may no longer be separated into different single materials via a mechanical method (such as: crushing, shearing, cutting, sawing, grinding, etc.) In a possible embodiment, the encapsulant that is the same or similar to the encapsulant 140 does not need to have an interface formed by different materials. In a possible embodiment, the encapsulant that is the same or similar to the encapsulant 140 does not need to have an interface formed by different processes (such as adhering to each other).

Referring to FIG. 1C to FIG. 1D, the second redistribution circuit structure 120 is formed on the second encapsulating surface 142 of the encapsulant 140.

The second redistribution circuit structure 120 may include a corresponding conductive layer 121 (indicated in FIG. 1G) and a corresponding insulating layer 122 (indicated in FIG. 1G). The second redistribution circuit structure 120 may be formed by a commonly used semiconductor process (e.g., coating process, deposition process, photolithography process, and/or etching process), so details are not repeated here. The number of layers of the conductive layer 121 and/or the insulating layer 122 is not limited in the invention. In addition, in FIG. 1D or other similar figures, the form of the conductive layer 121 and/or the insulating layer 122 is only shown as an example. For example, even though two adjacent conductive layers 121 are not connected in the cross section shown in FIG. 1D, two adjacent conductive layers 121 may still be connected in other cross sections not shown. A corresponding portion of the conductive layer 121 may form a corresponding circuit. In addition, the layout design of the circuit may be adjusted according to design requirements, which is not limited in the invention.

In addition, in order to make the drawings concise and clear, the conductive layer 121 and/or the insulating layer 122 are not directly marked in FIG. 1D or other similar drawings. A portion of the conductive layer 121 and/or the insulating layer 122 in the second redistribution circuit structure 120 may be as provided in FIG. 1G. In FIG. 1D or other similar figures, the corresponding boxed regions including oblique lines in the second redistribution circuit structure 120 may be the corresponding conductive layer 121, and/or the corresponding blank boxed regions in the redistribution circuit structure may be the corresponding insulating layer 122.

In an embodiment, the material of the insulating layer 122 of the second redistribution circuit structure 120 is, for example, polyimide (PI), other suitable organic insulating materials, or a stack or combination thereof.

In an embodiment, the top insulating layer 128 (i.e., the insulating layer 122 farthest from the encapsulant 140) may have an opening, and the opening may expose a portion of the top conductive layer 127 (i.e., the conductive layer 121 farthest from the encapsulant 140). In an embodiment, the portion of the top conductive layer 127 exposed by the opening may be called a contact pad.

In an embodiment, a portion of the top conductive layer 127 may form an alignment pattern. For example, a portion of the top conductive layer 127 may form an alignment pattern P1. A pattern and/or the position of the alignment pattern that is the same as or similar to the alignment pattern P1 may be adjusted according to design requirements, which is not limited in the invention. In an embodiment, in a subsequent application, there may not be any conductive member for transmitting electrical signals connected to the alignment pattern P1.

In an embodiment, if the rigid elements 133 are electronic elements (that is, possible; but not limited to), the rigid elements 133 having the form or function of an electronic element may be electrically connected to one or more corresponding circuits in the first redistribution circuit structure 110 and/or the second redistribution circuit structure 120 via a suitable conductive member on other cross-sections not shown. In an embodiment, if the rigid elements 133 are chips, the rigid elements 133 may be homogeneous chips or heterogeneous chips with the first chips 131, which is not limited in the invention.

Referring to FIG. 1E to FIG. 1F and/or FIG. 1K to FIG. 1L, a coded structure 152 is formed on the second redistribution circuit structure 120.

Referring to FIG. 1E and/or FIG. 1K, in an embodiment, a patterned insulating layer 151 may be formed on the second redistribution circuit structure 120.

In an embodiment, a thickness 151h (shown in FIG. 1G) of the insulating layer 151 may be about 25 micrometers (μm) to 30 micrometers. In this way, a portion of the corresponding insulating layer 151 may be adapted to form a coded pattern P2 described later.

Referring to FIG. 1F and/or FIG. 1L, a laser device 95 (shown in FIG. 1F) may be used to engrave a portion of the insulating layer 151 to form the corresponding coded pattern P2. Therefore, the portion of the insulating layer 151 having the coded pattern P2 may be regarded as the coded structure 152. That is, the coded structure 152 includes the corresponding coded pattern P2.

If a laser beam (e.g., a laser mean emitted from the laser device 95) forming the coded pattern P2 is applied to engrave a conductor (e.g., a metal), conductive particles produced by the applied laser beam may affect an electrical property of an electrical device. For example, conductive particles scattered between two circuits may cause an undesirable short circuit.

In an embodiment, before the insulating layer 151 is engraved via the laser device 95, the position of the alignment pattern P1 may be identified via a suitable alignment device, so as to further confirm the position to be engraved.

In an embodiment, the portion of the insulating layer 151 irradiated by the laser light may undergo structural and/or molecular changes due to light or heat and correspondingly result in carbonization, bubbling, melting, ablation, or other possible abrasions. The appearance (such as color, light penetration, or light dispersion) of the abrasions may be different from other portions of the insulating layer 151 not irradiated by laser light. For example, compared with the portion of the insulating layer 151 not engraved by laser, as shown in FIG. 1N, the outer surface of the portion of the insulating layer 151 engraved by laser has a larger surface roughness. The laser for forming the coded pattern P2 does not form any structural feature that penetrates through the insulation layer 151 (e.g., a through hole, a through groove, or a through trench). As another example, compared with the portion of the insulating layer 151 not engraved by laser, the portion of the outer surface of the insulating layer 151 after being engraved by laser has larger arithmetic mean deviation (Ra), maximum height of profile (Rz), maximum profile peak height (Rp), maximum profile valley depth (Rv), or total height of profile (Rt).

In an embodiment, the corresponding coded pattern P2 may be formed by the above method. In addition, for simplicity, the portions of the insulating layer 151 irradiated by the laser light and not irradiated by the laser light are marked with the same reference numerals.

In an embodiment, the material of the insulating layer 151 is different from the material of the top insulating layer 128 in the second redistribution circuit structure 120. In an embodiment, under visible light, the light transmittance of the insulating layer 151 is less than the light transmittance of the top insulating layer 128. Taking the insulating layer 151 having a thickness of about 25 micrometers (μm) to 30 micrometers as an example, the light transmittance thereof may be about 40% to 60% in the range of visible light. In this way, the alignment pattern P1 may be identified by a suitable alignment device; and the coded pattern P2 engraved on the insulating layer 151 may be adapted to be identified.

In an embodiment, the image of the coded pattern P2 may be suitable for being read by an image-capture device. Moreover, the corresponding readable data may be extracted from the image of the coded pattern P2 by a suitable image identification and/or decoding method. For example, the coded pattern P2 may include barcode, text, and/or graphics. The barcode may include, for example, a 1D barcode or a 2D barcode. The 1D barcode may include, but not limited to: Interleaved 2 of 5 (ITF code), EAN-13 code, EAN-8 code, Codabar code, Universal Product code (UPC code), Code 93 code, Code 11 code, MSI code, Plessey code, Toshiba code, Code 32 code, RSS code. The 2D barcode may include, but not limited to: Quick Response Code (QR code), PDF417 2D code, a combination code of 1D Barcode and PDF417 code, or Data Matrix code. The barcode may be captured by an image sensor, a camera, or any suitable image-capture device, and then the captured image may be decoded by a processor to provide product information corresponding to the first chips 131 or the package structure (e.g., a package structure 101, 102, or 103 described later). The product information may include supplier information, manufacturer information, production date, part number, batch number, and/or material number of the first chips 131 or the package structure (such as the package structure 101, 102, or 103 described later), and may be presented by text transmission/representation, download of data content, quick connection of webpage, transmission of short message, dialing of telephone, and/or other suitable methods. In other words, the coded pattern P2 may be read more quickly, and may contain more information or data than simple symbols (such as letters or numbers). Therefore, via the coded pattern P2, the following operations may be facilitated, for example: product tracking, identification or recognition; and various applications such as production management, inventory management, and/or sales management may be efficiently performed.

In an embodiment, in a top view state (such as shown in FIG. 1L or other similar figures), the coded pattern P2 is not overlapped with the alignment pattern P1. In this way, the resolution of the coded pattern P2 may be improved.

In an embodiment, a portion of the coded structure 152 covers and/or overlaps the alignment pattern P1. For example, a specific portion of coding structure 152 except the coded pattern P2 may covers and/or overlaps the alignment pattern P1. Additionally, since the coding structure 152 has an appropriate thickness (e.g., 25 μm˜30 μm) and/or light transmittance (e.g., about 40% to 60% in the range of visible light), the alignment pattern P1 covered and/or overlapped by the coding structure 152 may still be used for alignment in a subsequent process or a corresponding structure.

In an embodiment, in a top view state, the coded pattern P2 does not need to be overlapped with the top conductive layer 127. In this way, metal reflection interference may possibly be reduced, and the resolution of the coded pattern P2 may be improved. In an embodiment, in a top view (e.g., as shown in FIGS. 1K and/and 1L), the coded pattern P2 is not overlapped any conductive layer (e.g., any one of the conductive layers 121) of the second redistribution circuit structure 120. As such, metal reflection interference may almost be avoided.

Please refer to FIG. 1F and/or FIG. 1L, in an embodiment, other portions of the insulating layer 151 not engraved by the laser device (shown in FIG. 1F) may be used as a dam structure 153.

In an embodiment, the dam structure 153 and the coded structure 152 are structurally separated from each other.

Referring to FIG. 1F to FIG. 1G, a singulation process may be performed on the structure on the carrier 91 in FIG. 1F. The singulation process includes, for example, cutting the structure on the carrier 91 (shown in FIG. 1G) with a rotary blade or a laser beam. In an embodiment, the singulation process may be further performed on the first redistribution circuit structure 110, the encapsulant 140, and/or the second redistribution circuit structure 120.

It is worth noting that after the singulation process is performed, similar reference numerals are used for the singulated elements. For example, the first redistribution circuit structure 110 (as shown in FIG. 1F) may be the first redistribution circuit structure 110 (as shown in FIG. 1G) after singulation, the first chips 131 (as shown in FIG. 1F) may be the first chips 131 (as shown in FIG. 1G) after singulation, the conductive members 145 (as shown in FIG. 1F) may be the plurality of conductive members 145 (as shown in FIG. 1G) after singulation, the rigid elements 133 (as shown in FIG. 1F) may be the rigid elements 133 (as shown in FIG. 1G) after singulation, the encapsulant 140 (as shown in FIG. 1F) may be the encapsulant 140 (as shown in FIG. 1G) after singulation, and the second redistribution circuit structure 120 (as shown in FIG. 1F) may be the second redistribution circuit structure 120 (as shown in FIG. 1G) after singulation, and so on. Other elements after singulation follow the same reference numeral rules as above, and are not repeated here. In addition, for clarity, not all elements are marked one by one in FIG. 1G.

Referring to FIG. 1F to FIG. 1G, the carrier 91 is separated from the first redistribution circuit structure 110; then, corresponding conductive terminals 161 are formed on the first redistribution circuit structure 110 (lower portion in FIG. 1G). In addition, for clarity, not all the conductive terminals 161 are marked one by one in FIG. 1G or other similar figures.

It should be noted that some of the above steps may be adjusted according to the demands of the manufacturing process.

For example, in the above embodiments, the patterned insulating layer 151 may be formed first; then, after the insulating layer 151 is formed, the coded structure 152 is formed; then, a singulation process is performed; and then, the carrier 91 is removed and the corresponding conductive terminals 161 are formed.

For example, in an embodiment not shown, the patterned insulating layer 151 may be formed first; then, after the insulating layer 151 is formed, the coded structure 152 is formed; then, the carrier 91 is removed and the corresponding conductive terminals 161 are formed; then, the singulation process is performed.

For example, in an embodiment not shown, the singulation process may be performed first; then, the carrier 91 is removed and the corresponding conductive terminals 161 are formed; then, the patterned insulating layer 151 is formed; and then, the coded structure 152 is formed after the insulating layer 151 is formed.

For example, in an embodiment not shown, the patterned insulating layer 151 may be formed first; then, the singulation process is performed; then, the coded structure 152 is formed after the insulating layer 151 is formed; then, the carrier 91 is removed and corresponding conductive terminals 161 are formed.

For example, in an embodiment not shown, first, the carrier 91 is removed and the corresponding conductive terminals 161 are formed; then, the patterned insulating layer 151 is formed; then, the coded structure 152 is formed after the insulating layer 151 is formed; and then, the singulation process is performed.

After the above manufacturing process, the manufacture of the package structure 101 of the present embodiment may be substantially completed.

FIG. 1G may be a partial cross-sectional schematic diagram of a package structure according to the first embodiment of the invention. FIG. 1L may be a partial top schematic diagram of a package structure according to the first embodiment of the invention. FIG. 1N is a partial cross-sectional schematic diagram of a package structure according to the first embodiment of the invention. For example, FIG. 1N may be a partial cross-sectional schematic diagram corresponding to the region having the coded pattern P2 (i.e., the partial region of the insulating layer 151 after being engraved by the laser device 95) in FIG. 1L. That is, if the package structure 101 is described, at least the contents and corresponding descriptions shown in FIG. 1G, FIG. 1L, and FIG. 1N need to be considered. Of course, a portion of the structural details may be related to the above manufacturing process. Therefore, when describing the package structure 101, the contents and corresponding descriptions shown in FIG. 1A to FIG. 1G and FIG. 1K may also be considered.

The package structure 101 includes the first chips 131, the encapsulant 140, the first redistribution circuit structure 110, the second redistribution circuit structure 120, the conductive members 145, and the coded structure 152. The encapsulant 140 has a first encapsulating surface 141 and a second encapsulating surface 142. The second encapsulating surface 142 is opposite to the first encapsulating surface 141. The encapsulant 140 at least laterally covers the first chips 131. The first redistribution circuit structure 110 is disposed on the first encapsulating surface (lower portion in FIG. 1G) of the encapsulant 140. The second redistribution circuit structure 120 is disposed on the second encapsulating surface 142 (upper portion in FIG. 1G) of the encapsulant 140. The conductive members 145 penetrate through the encapsulant 140 to be electrically connected to the corresponding circuit in the first redistribution circuit structure 110 and the corresponding circuit in the second redistribution circuit structure 120. The first chips 131 may be electrically connected to the corresponding circuit in the second redistribution circuit structure 120; or, the first chips 131 may be electrically connected to the corresponding circuit in the first redistribution circuit structure 110 via the corresponding circuit in the second redistribution circuit structure 120 and the corresponding conductive members 145. The coded structure 152 is disposed on the second redistribution circuit structure 120. The material of the coded structure 152 includes a non-conductor. The coded structure 152 includes the readable coded pattern P2. In an embodiment, the entire material of the coded structure or any portion of the coded structure is electrically non-conductive.

Please refer to FIG. 1G to FIG. 1H, in an embodiment, second chips 132 may be disposed on the second redistribution circuit structure 120, and the second chips 132 may be electrically connected to the corresponding circuit in the second redistribution circuit structure 120.

In an embodiment, the second chips 132 may be disposed on the second redistribution circuit structure 120 by means of flip-chip bonding and electrically connected to the corresponding circuit therein.

After the above manufacturing process, the manufacture of the package structure 102 of the present embodiment may be substantially completed.

FIG. 1H may be a partial cross-sectional schematic diagram of a package structure according to the first embodiment of the invention.

The package structure 102 is similar to the package structure 101, so descriptions of parts with similar features are not repeated. That is, if the package structure 102 is described, at least the contents and corresponding descriptions shown in FIG. 1G, FIG. 1H, FIG. 1L, and FIG. 1N need to be considered. Of course, a portion of the structural details may be related to the above manufacturing process. Therefore, when describing the package structure 102, the contents and corresponding descriptions shown in FIG. 1A to FIG. 1G and FIG. 1K may also be considered.

The package structure 102 includes the first chips 131, the second chips 132, the encapsulant 140, the first redistribution circuit structure 110, the second redistribution circuit structure 120, the conductive members 145, and the coded structure 152. The second chips 132 are disposed on the second redistribution circuit structure 120 and electrically connected to the corresponding circuit therein.

Referring to FIG. 1H to FIG. 1I, in an embodiment, an underfill layer 138 may be formed between the second chips 132 and the second redistribution circuit structure 120. The underfill layer 138 is formed by, for example, capillary underfill (CUF) or other suitable filling colloids. For example, an underfill colloid may be filled at least between the second chips 132 and the second redistribution circuit structure 120; then, the corresponding underfill layer 138 may be formed by a suitable curing method.

In an embodiment, during the forming of the underfill layer 138, the dam structure 153 may at least partially restrict the flow range of the uncured colloid. It should be noted that the dam structure 153 only needs to partially restrict the flow range of the uncured colloid. That is to say, the dam structure 153 may be formed by a plurality of structures structurally separated from each other, but the invention does not limit that the plurality of structures separated from each other need to form a closed ring (but still may).

In an embodiment, the dam structure 153 may surround the second chips 132 in a top view (e.g., as shown in FIG. 1M). In an embodiment, the dam structure 153 may surround the underfill layer 138 in a top view.

In an embodiment, during the forming of the underfill layer 138, the coded structure 152 may also partially restrict the flow range of the uncured colloid. That is, in a top view, the underfill layer 138 is not overlapped with the coded pattern P2. In this way, the coded P2 may be adapted to be read.

After the above manufacturing process, the manufacture of the package structure 103 of the present embodiment may be substantially completed.

FIG. 1I may be a partial cross-sectional schematic diagram of a package structure according to the first embodiment of the invention. FIG. 1M is a partial top view schematic diagram of a package structure according to the first embodiment of the invention. For example, FIG. 1M may be a schematic top view corresponding to a portion of FIG. 1I.

The package structure 103 is similar to the package structure 101 or 102, so descriptions of parts with similar features are not repeated. That is, if the package structure 103 is described, at least the contents and corresponding descriptions shown in FIG. 1G to FIG. 1I and FIG. 1L to FIG. 1N need to be considered. Of course, a portion of the structural details may be related to the above manufacturing process. Therefore, when describing the package structure 103, the contents and corresponding descriptions shown in FIG. 1A to FIG. 1G and FIG. 1K may also be considered.

The package structure 103 includes the first chips 131, the second chips 132, the encapsulant 140, the first redistribution circuit structure 110, the second redistribution circuit structure 120, the conductive members 145, the coded structure 152, and the underfill layer 138. The underfill layer 138 is disposed between the second chips 132 and the second redistribution circuit structure 120.

Please refer to FIG. 1I to FIG. 1J, in an embodiment, a casing 163 may be disposed on the second redistribution circuit structure 120.

In the present embodiment, there may be an adhesive layer 162 between the second chips 132 and the casing 163.

In the present embodiment, the casing 163 may include a heat dissipation casing 163. For example, the adhesive layer 162 may be a thermally conductive adhesive layer. During the operation of a package structure 104, the second chips 132 may be thermally coupled to the casing 163 via the thermally conductive adhesive layer, so that at least the heat generated by the second chips 132 may be dissipated more efficiently.

In the present embodiment, the casing 163 may include an electromagnetic interference (EMI) shielding casing or other similar shielding bodies.

In an embodiment not shown, at least one certain corresponding circuit in the second redistribution circuit structure 120 may be electrically connected to the casing 163.

In an embodiment, during the forming of the underfill layer 138, the dam structure 153 may at least partially restrict the flow range of the uncured colloid. In this way, the casing 163 may be disposed more readily.

After the above manufacturing process, the manufacture of the package structure 104 of the present embodiment may be substantially completed.

FIG. 1J may be a partial cross-sectional schematic diagram of a package structure according to the first embodiment of the invention.

The package structure 104 is similar to the package structure 101, 102, or 103, so descriptions of parts with similar features are not repeated. That is, if the package structure 104 is described, at least the contents and corresponding descriptions shown in FIG. 1G to FIG. 1J and FIG. 1L to FIG. 1N need to be considered. Of course, a portion of the structural details may be related to the above manufacturing process. Therefore, when describing the package structure 104, the contents and corresponding descriptions shown in FIG. 1A to FIG. 1G and FIG. 1K may also be considered.

The package structure 104 includes the first chips 131, the second chips 132, the encapsulant 140, the first redistribution circuit structure 110, the second redistribution circuit structure 120, the conductive members 145, the coded structure 152, the underfill layer 138, and the casing 163. The casing 163 is disposed on the second redistribution circuit structure 120.

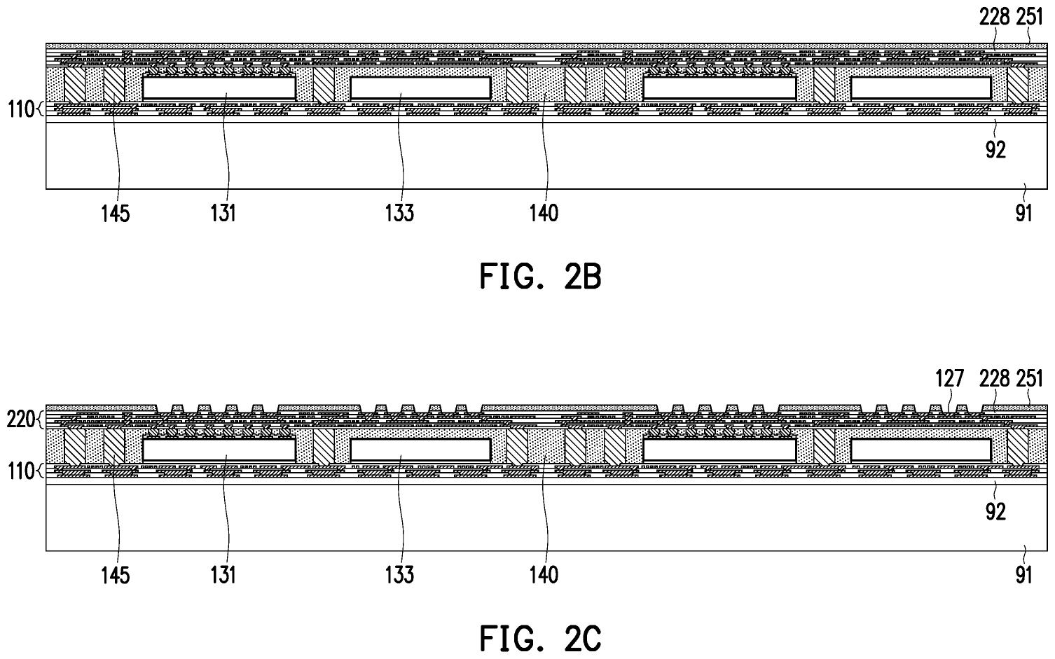

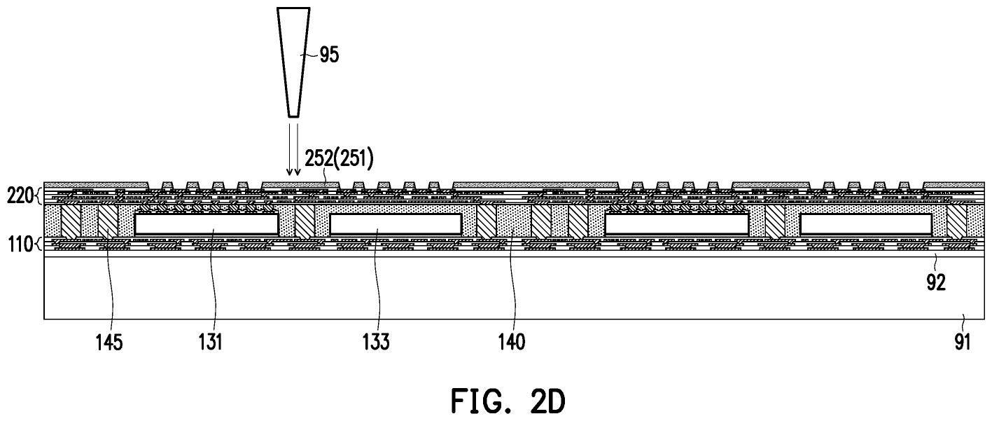

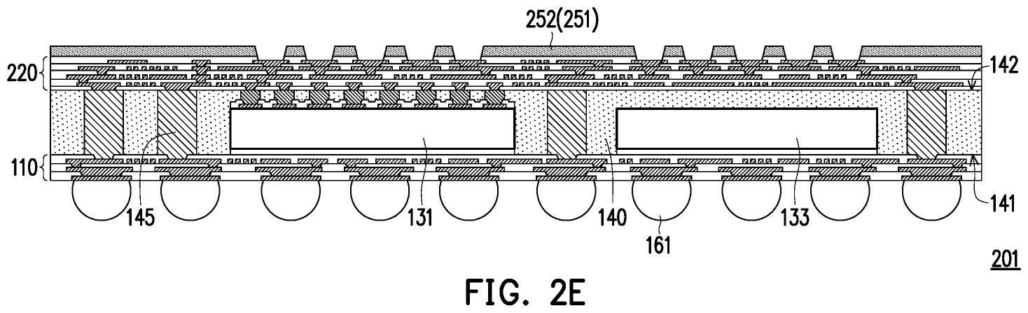

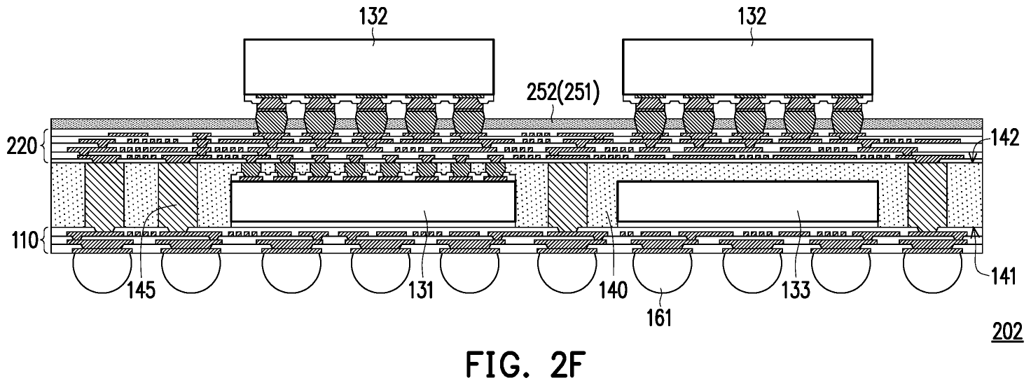

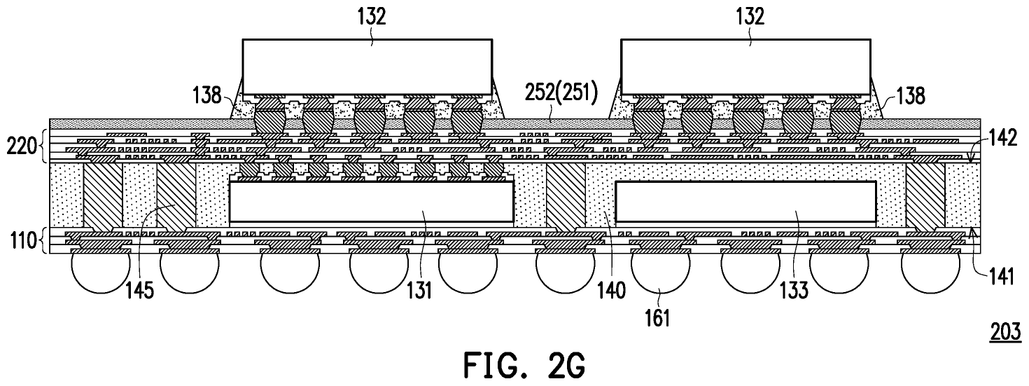

FIG. 2A to FIG. 2E are partial cross-sectional schematic diagrams of a partial manufacturing method of a package structure according to the second embodiment of the invention. The manufacturing method of the package structure of the present embodiment is similar to the manufacturing method of the first embodiment, and similar members thereof are denoted by the same reference numerals and have similar functions, materials, or forming methods, and descriptions thereof are omitted. Specifically, FIG. 2A to FIG. 2E are cross-sectional schematic diagrams showing the manufacturing method of the package structure subsequent to the step in FIG. 1C.

Referring to FIG. 1C and FIG. 2A to FIG. 2D, in an embodiment, forming a second redistribution circuit structure 220 and a coded structure 252 on the second encapsulating surface 142 of the encapsulant 140 may be as follows.

Referring to FIG. 1C and FIG. 2A, a corresponding conductive layer (may be not directly marked for simplicity and clarity in the drawings; may be a boxed region including oblique lines) and a corresponding insulating layer (may be not directly marked for the simplicity and clarity in the drawings; may be a blank boxed region) are formed on the second encapsulating surface 142 of the encapsulant 140. The conductive layer and/or the insulating layer may be formed by a commonly used semiconductor process (e.g., coating process, deposition process, photolithography process, and/or etching process), so details are not repeated here.

Referring to FIG. 2A to FIG. 2B, an insulating layer 251 is formed on a top insulating layer 228.

In an embodiment, the insulating layer 251 may be formed by coating.

In an embodiment, the thickness of the insulating layer 251 may range from 25 micrometers (μm) to 30 micrometers. In this way, the forming of a coded pattern described later may be facilitated.

In an embodiment, the material of the insulating layer 251 is different from the material of the insulating layer 228. In an embodiment, under visible light, the light transmittance of the insulating layer 251 is less than the light transmittance of the insulating layer 228.

Referring to FIG. 2B to FIG. 2C, a portion of the insulating layer 251 and a portion of the insulating layer 228 are removed to form corresponding openings exposing a portion of the top conductive layer 127. In addition, for simplicity, the insulating layer 251 and the insulating layer 228 having corresponding openings still adopt the same reference numerals.

In an embodiment, the insulating layer 251 having corresponding openings, other insulating layers (may be not directly marked), and corresponding conductive layers (may be not directly marked) may form the second redistribution circuit structure 220.

In an embodiment, the structure of the second redistribution circuit structure 220 may be the same as or similar to the structure of the second redistribution circuit structure 120 of the above embodiments, and the difference may be in the forming method or sequence. That is, when describing the structure of the second redistribution circuit structure 220, the description of the structure of the second redistribution circuit structure 120 may be adopted.

Referring to FIG. 2D, the insulating layer 251 may be engraved by the laser device 95 to form a corresponding coded pattern. The appearance or purpose of the coded pattern may be the same as or similar to the appearance or purpose of the coded pattern P2 (for example: marked in FIG. 1L or other similar drawings), so is not repeated here. In addition, for simplicity, the portions of the insulating layer 251 irradiated by the laser light and not irradiated by the laser light are marked with the same reference numerals.

In an embodiment, the portion of the insulating layer 251 having the coded pattern may be referred to as the coded structure 252.

In an embodiment, the structure of the coded structure 252 may be the same as or similar to the structure of the coded structure 152 of the above embodiments, and the difference may be in the forming method or sequence. That is, when describing the structure of the coded structure 252, the description of the structure of the coded structure 152 may be adopted.

In an embodiment, an opening exposing the top conductive layer 127 may be formed first; then, the coded structure 252 is formed. In an embodiment not shown, the coded structure 252 may be formed first; then, an opening exposing the top conductive layer 127 is formed.

In an embodiment, the opening exposing the top conductive layer 127 may be formed by a laser device. For example, the opening exposing the top conductive layer 127 may be formed by the laser device 95, and the difference is in the power or energy of the laser light.

Referring to FIG. 2D to FIG. 2E, a singulation process may be performed on the structure on the carrier 91 in FIG. 2D. It is worth noting that after the singulation process is performed, similar reference numerals are used for the singulated elements.

Referring to FIG. 2D to FIG. 2E, the carrier 91 is separated from the first redistribution circuit structure 110; then, the corresponding conductive terminals 161 are formed on the first redistribution circuit structure 110 (lower portion in FIG. 2E).

It should be noted that some of the above steps may be adjusted according to the demands of the manufacturing process.

After the above manufacturing process, the manufacture of the package structure 201 of the present embodiment may be substantially completed.

FIG. 2E may be a partial cross-sectional schematic diagram of a package structure according to the second embodiment of the invention. The package structure 201 is similar to the package structure 101. That is, if the package structure 201 is described, at least the contents and corresponding descriptions shown in FIG. 2E should be considered; or, the contents and corresponding descriptions shown in FIG. 1G, FIG. 1L, and FIG. 1N should be further considered. Of course, a portion of the structural details may be related to the above manufacturing process. Therefore, when describing the package structure 201, the contents and corresponding descriptions shown in FIG. 1A to FIG. 1C and FIG. 2A to FIG. 2E may also be considered.

The package structure 201 includes the first chips 131, the encapsulant 140, the first redistribution circuit structure 110, the second redistribution circuit structure 220, the conductive members 145, and the coded structure 252. The second redistribution circuit structure 220 is disposed on the second encapsulating surface 142 (upper portion in FIG. 2E) of the encapsulant 140. The conductive members 145 penetrate through the encapsulant 140 to be electrically connected to the corresponding circuit in the first redistribution circuit structure 110 and the corresponding circuit in the second redistribution circuit structure 220. The first chips 131 may be electrically connected to the corresponding circuit in the second redistribution circuit structure 220; or, the first chips 131 may be electrically connected to the corresponding circuit in the first redistribution circuit structure 110 via the corresponding circuit in the second redistribution circuit structure 220 and the corresponding conductive members 145. The coded structure 252 is disposed on the second redistribution circuit structure 220. The material of the coded structure 252 includes a non-conductor. The coded structure 252 includes a readable coded pattern (e.g., the coded pattern P2; shown in FIG. 1L or other similar drawings).

Please refer to FIG. 2E to FIG. 2F, in an embodiment, the second chips 132 may be disposed on the second redistribution circuit structure 220, and the second chips 132 may be electrically connected to the corresponding circuit in the second redistribution circuit structure 220.

After the above manufacturing process, the manufacture of a package structure 202 of the present embodiment may be substantially completed.

FIG. 2F may be a partial cross-sectional schematic diagram of a package structure according to the second embodiment of the invention.

The package structure 202 is similar to the package structure 201, 101, or 102, so descriptions of parts with similar features are not repeated. That is, if the package structure 202 is described, at least the contents and corresponding descriptions shown in FIG. 2E and FIG. 2F should be considered; or, the contents and corresponding descriptions shown in FIG. 1G, FIG. 1L, FIG. 1N, and FIG. 1H should be further considered. Of course, a portion of the structural details may be related to the above manufacturing process. Therefore, when describing the package structure 202, the contents and corresponding descriptions shown in FIG. 1A to FIG. 1C and FIG. 2A to FIG. 2E may also be considered.

The package structure 202 includes the first chips 131, the second chips 132, the encapsulant 140, the first redistribution circuit structure 110, the second redistribution circuit structure 220, the conductive members 145, and the coded structure 252. The second chips 132 are disposed on the second redistribution circuit structure 220 and electrically connected to the corresponding circuit therein.

Referring to FIG. 2F to FIG. 2G, in an embodiment, the underfill layer 138 may be formed between the second chips 132 and the second redistribution circuit structure 220. For example, an underfill colloid may be filled at least between the second chips 132 and the insulating layer 251; then, the corresponding underfill layer 138 may be formed by a suitable curing method.

After the above manufacturing process, the manufacture of a package structure 203 of the present embodiment may be substantially completed.

FIG. 2G may be a partial cross-sectional schematic diagram of a package structure according to the second embodiment of the invention.

The package structure 203 is similar to the package structure 201, 202, 101, 102, or 103, so descriptions of parts with similar features are not repeated. That is, if the package structure 203 is described, at least the contents and corresponding descriptions shown in FIG. 2E to FIG. 2G should be considered; or, the contents and corresponding descriptions shown in FIG. 1G, FIG. 1L, FIG. 1N, and FIG. 1H should be further considered. Of course, a portion of the structural details may be related to the above manufacturing process. Therefore, when describing the package structure 203, the contents and corresponding descriptions shown in FIG. 1A to FIG. 1C and FIG. 2A to FIG. 2E may also be considered.

The package structure 203 includes the first chips 131, the second chips 132, the encapsulant 140, the first redistribution circuit structure 110, the second redistribution circuit structure 220, the conductive members 145, the coded structure 252, and the underfill layer 138. The underfill layer 138 is disposed between the second chips 132 and the second redistribution circuit structure 220.

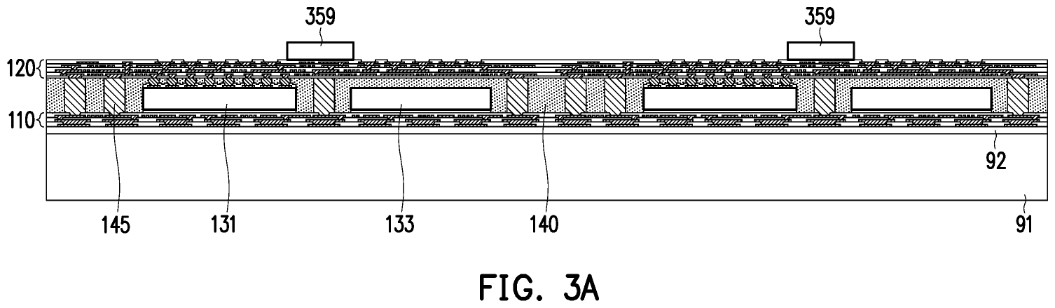

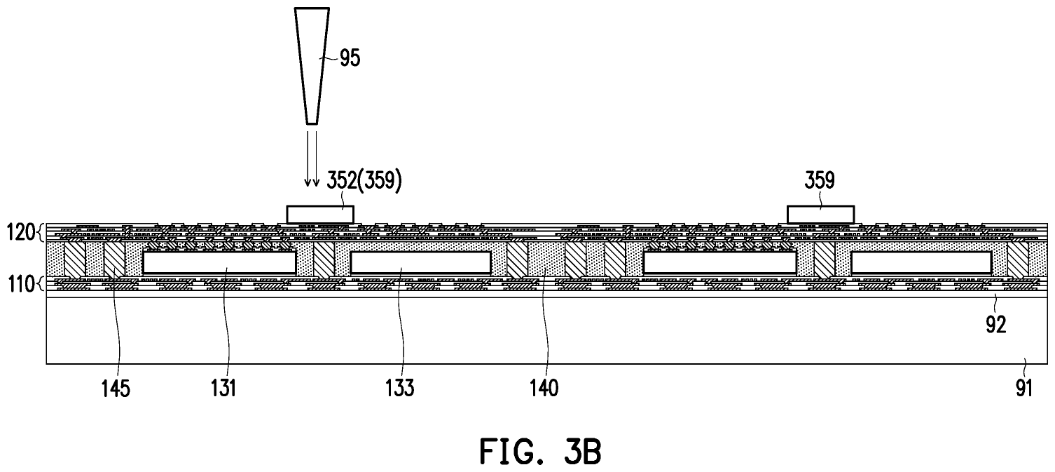

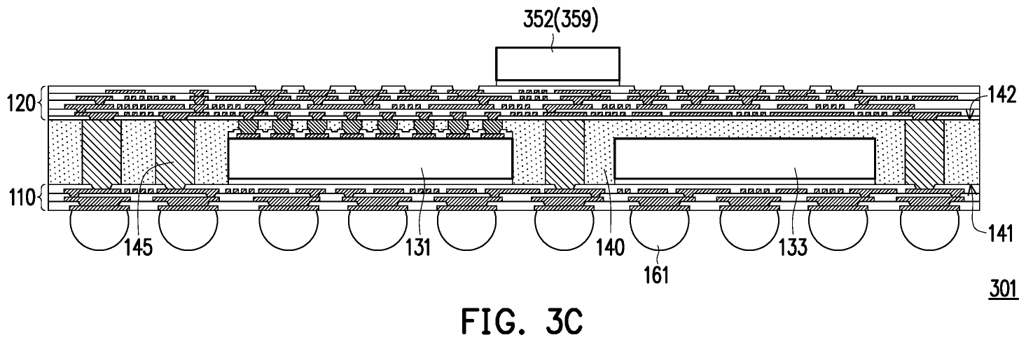

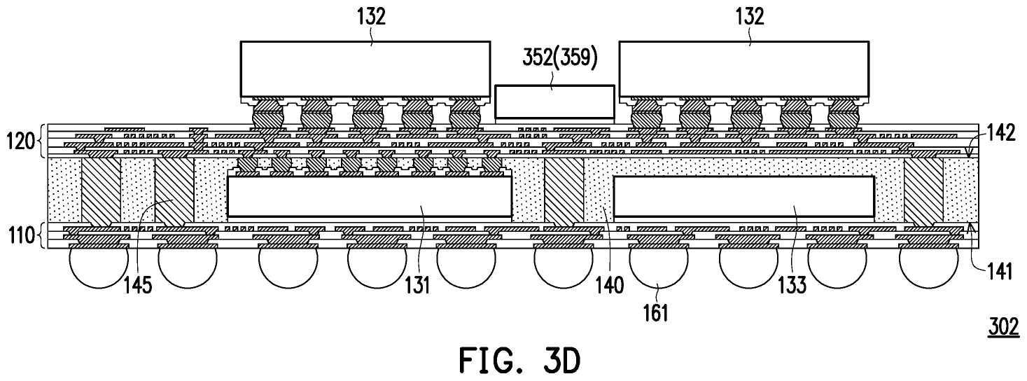

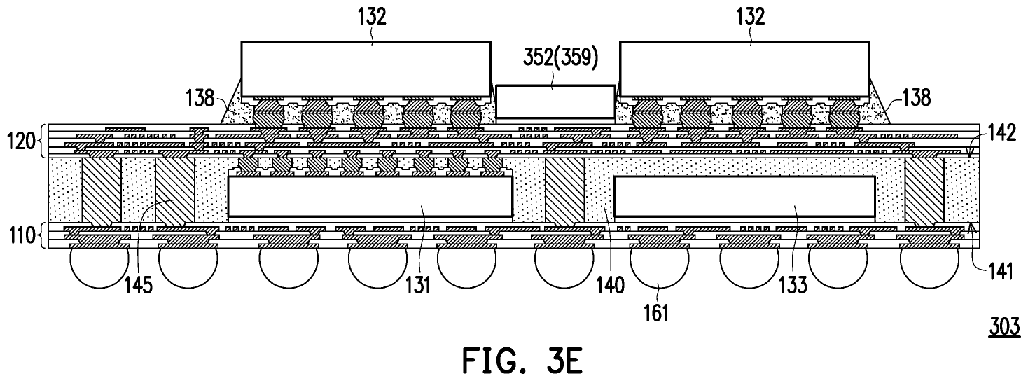

FIG. 3A to FIG. 3C are partial cross-sectional schematic diagrams of a partial manufacturing method of a package structure according to the third embodiment of the invention. The manufacturing method of the package structure of the present embodiment is similar to the manufacturing method of the first embodiment, and similar members thereof are denoted by the same reference numerals and have similar functions, materials, or forming methods, and descriptions thereof are omitted. Specifically, FIG. 3A to FIG. 3C are cross-sectional schematic diagrams showing the manufacturing method of the package structure subsequent to the step in FIG. 1D.

Referring to FIG. 1D and FIG. 3A to FIG. 3C, in an embodiment, forming a coded structure 352 on the second redistribution circuit structure 120 may be as follows.

Referring to FIG. 1D and FIG. 3A, a substrate 359 is disposed on the second redistribution circuit structure 120. For example, by means of a suitable device (e.g., pick-and-place apparatus) or method (e.g., pick-and-place process), the substrate 359 having a suitable size is disposed on the second redistribution circuit structure 120.

In an embodiment, the substrate 359 includes, for example, a silicon substrate, a ceramic substrate, a hard-plastic substrate, or other suitable non-conductive substrates.

Referring to FIG. 3B, the substrate 359 may be engraved by the laser device 95 to form a corresponding coded pattern. The appearance or purpose of the coded pattern may be the same as or similar to the appearance or purpose of the coded pattern P2 (for example: marked in FIG. 1L or other similar drawings), so is not repeated here. In addition, for simplicity, the portions of the substrate 359 irradiated by the laser light and not irradiated by the laser light are marked with the same reference numerals.

In an embodiment, the portion of the substrate 359 having the coded pattern may be referred to as the coded structure 352.

It should be noted that some of the above steps may be adjusted according to the demands of the manufacturing process.

For example, in the above embodiments, first, the substrate 359 is disposed on the second redistribution circuit structure 120; then, laser engraving is performed on the substrate 359 disposed on the second redistribution circuit structure 120. In an embodiment not shown, the substrate 359 engraved by laser may be disposed on the second redistribution circuit structure 120.

In an embodiment, there may be a corresponding adhesive layer between the substrate 359 and the second redistribution circuit structure 120.

Referring to FIG. 3B to FIG. 3C, a singulation process may be performed on the structure on the carrier 91 in FIG. 3B. It is worth noting that after the singulation process is performed, similar reference numerals are used for the singulated elements.

Referring to FIG. 3B to FIG. 3C, the carrier 91 is separated from the first redistribution circuit structure 110; then, the corresponding conductive terminal 161 are formed on the first redistribution circuit structure 110 (lower portion in FIG. 3C).

It should be noted that some of the above steps may be adjusted according to the demands of the manufacturing process.

After the above manufacturing process, the manufacture of a package structure 301 of the present embodiment may be substantially completed.

FIG. 3C may be a partial cross-sectional schematic diagram of a package structure according to the third embodiment of the invention. The package structure 301 is similar to the package structure 101. That is, if the package structure 301 is described, at least the contents and corresponding descriptions shown in FIG. 3C should be considered; or, the contents and corresponding descriptions shown in FIG. 1G, FIG. 1L, and FIG. 1N should be further considered. Of course, a portion of the structural details may be related to the above manufacturing process. Therefore, when describing the package structure 301, the contents and corresponding descriptions shown in FIG. 1A to FIG. 1D and FIG. 3A to FIG. 3C may also be considered.

The package structure 301 includes the first chips 131, the encapsulant 140, the first redistribution circuit structure 110, the second redistribution circuit structure 120, the conductive members 145, and the coded structure 352. The coded structure 352 is disposed on the second redistribution circuit structure 120. The material of the coded structure 352 includes a non-conductor. The coded structure 352 includes a readable coded pattern (e.g., the coded pattern P2; shown in FIG. 1L or other similar drawings).

Please refer to FIG. 3C to FIG. 3D, in an embodiment, the second chips 132 may be disposed on the second redistribution circuit structure 120, and the second chips 132 may be electrically connected to the corresponding circuit in the second redistribution circuit structure 120.

After the above manufacturing process, the manufacture of a package structure 302 of the present embodiment may be substantially completed.

FIG. 3D may be a partial cross-sectional schematic diagram of a package structure according to the third embodiment of the invention.

The package structure 302 is similar to the package structure 301, 101, or 102, so descriptions of parts with similar features are not repeated. That is, if the package structure 302 is described, at least the contents and corresponding descriptions shown in FIG. 3C and FIG. 3D should be considered; or, the contents and corresponding descriptions shown in FIG. 1G, FIG. 1L, FIG. 1N, and FIG. 1H should be further considered. Of course, a portion of the structural details may be related to the above manufacturing process. Therefore, when describing the package structure 302, the contents and corresponding descriptions shown in FIG. 1A to FIG. 1D and FIG. 3A to FIG. 3C may also be considered.

The package structure 302 includes the first chips 131, the second chips 132, the encapsulant 140, the first redistribution circuit structure 110, the second redistribution circuit structure 120, the conductive members 145, and the coded structure 352. The second chips 132 are disposed on the second redistribution circuit structure 120 and electrically connected thereto.

Referring to FIG. 3D to FIG. 3E, in an embodiment, the underfill layer 138 may be formed between the second chips 132 and the second redistribution circuit structure 120.

After the above manufacturing process, the manufacture of a package structure 303 of the present embodiment may be substantially completed.

FIG. 3E may be a partial cross-sectional schematic diagram of a package structure according to the third embodiment of the invention.

The package structure 303 is similar to the package structure 301, 302, 101, 102, or 103, so descriptions of parts with similar features are not repeated. That is, if the package structure 303 is described, at least the contents and corresponding descriptions shown in FIG. 2C and FIG. 2E should be considered; or, the contents and corresponding descriptions shown in FIG. 1G, FIG. 1L, FIG. 1N, and FIG. 1H should be further considered. Of course, a portion of the structural details may be related to the above manufacturing process. Therefore, when describing the package structure 303, the contents and corresponding descriptions shown in FIG. 1A to FIG. 1D and FIG. 3A to FIG. 3C may also be considered.

The package structure 303 includes the first chips 131, the second chips 132, the encapsulant 140, the first redistribution circuit structure 110, the second redistribution circuit structure 120, the conductive members 145, the coded structure 352, and the underfill layer 138. The underfill layer 138 is disposed between the second chips 132 and the second redistribution circuit structure 120.

Based on the above, in an embodiment of the invention, via the coded structure, efficient product tracking, identification, or recognition may be performed during the manufacturing process of the package structure or the finished product thereof, and/or the manufacturing process of the package structure or the finished product may be efficiently managed.

What is claimed is:

1. A package structure, comprising:
a first chip;
an encapsulant having a first encapsulating surface and a second encapsulating surface opposite to the first encapsulating surface and covering the first chip;
a first redistribution circuit structure disposed on the first encapsulating surface of the encapsulant;
a second redistribution circuit structure disposed on the second encapsulating surface of the encapsulant, wherein the first chip is electrically connected to the first redistribution circuit structure or the second redistribution circuit structure;
a conductive member penetrating through the encapsulant to be electrically connected to the first redistribution circuit structure and the second redistribution circuit structure; and
a coded structure disposed on the second redistribution circuit structure, wherein the coded structure comprises a readable coded pattern.

2. The package structure of claim 1, wherein the coded pattern is formed by laser engraving.

3. The package structure of claim 1, wherein a machine is adapted to extract product information containing at least one of the first chip or the package structure from an image of the coded pattern.

4. The package structure of claim 1, wherein the second redistribution circuit structure comprises:
a top conductive layer; and
a top insulating layer covering the top conductive layer, wherein the coded structure does not directly cover the top conductive layer.

5. The package structure of claim 1, wherein the second redistribution circuit structure comprises:
a top conductive layer; and
a top insulating layer covering the top conductive layer, wherein a material of the coded structure comprises an insulating material different from the top insulating layer.

6. The package structure of claim 5, wherein under a visible light, a light transmittance of the insulating material of the coded structure is less than a light transmittance of the top insulating layer.

7. The package structure of claim 1, further comprising:
an alignment pattern, wherein the second redistribution circuit structure comprises a top conductive layer and a top insulating layer covering the top conductive layer, and the alignment pattern is formed by a portion of the top conductive layer.

8. The package structure of claim 7, wherein the coded pattern and the alignment pattern are not overlapped.

9. The package structure of claim 1, further comprising:
an alignment pattern, wherein a portion of the coded structure covers and/or overlaps the alignment pattern.

10. The package structure of claim 1, further comprising:
a dam structure, wherein the coded structure and the dam structure comprise a same insulating layer; and
an alignment pattern, wherein a portion of the insulating layer covers and/or overlaps the alignment pattern.

11. The package structure of claim 1, further comprising:
a second chip disposed on the second redistribution circuit structure and electrically connected to the second redistribution circuit structure.

12. The package structure of claim 11, further comprising:
an underfill layer disposed between the second chip and the second redistribution circuit structure; and
a dam structure disposed on the second redistribution circuit structure and surrounding the underfill layer.

13. The package structure of claim 12, wherein the coded structure and the dam structure comprise a same insulating layer.

14. A manufacturing method of a package structure, comprising:
forming a first redistribution circuit structure;
forming a conductive member on the first redistribution circuit structure;
disposing a first chip on the first redistribution circuit structure;
forming an encapsulant on the first redistribution circuit structure to cover the first chip;
forming a second redistribution circuit structure on the encapsulant, wherein the first chip is electrically connected to the first redistribution circuit structure or the second redistribution circuit structure, and the conductive member penetrates through the encapsulant to be electrically connected to the first redistribution circuit structure and the second redistribution circuit structure; and
forming a coded structure on the encapsulant, wherein the coded structure comprises a readable coded pattern.

15. The manufacturing method of the package structure of claim 14, wherein the coded pattern is formed by laser engraving.

16. The manufacturing method of the package structure of claim 14, wherein the step of forming the second redistribution circuit structure comprises:
forming a top conductive layer; and
forming a top insulating layer covering the top conductive layer, wherein a material of the coded structure comprises an insulating material different from the top insulating layer.

17. The manufacturing method of the package structure of claim 14, wherein the step of forming the second redistribution circuit structure comprises:
forming a top conductive layer; and
forming a top insulating layer to cover the top conductive layer, wherein a portion of the top conductive layer forms an alignment pattern, and the coded pattern and the alignment pattern are not overlapped.
